(19) United States
(12) Patent Application Publication
(10) Pub. No.: US 2025/0356907 A1
(43) Pub. Date: Nov. 20, 2025

(54) SEMICONDUCTOR STRUCTURES IN MEMORY DEVICES

(71) Applicant: Yangtze Memory Technologies Co., Ltd., Wuhan (CN)

(72) Inventors: Xu HOU, Wuhan (CN); Shouchun PENG, Wuhan (CN)

(21) Appl. No.: 18/790,567

(22) Filed: Jul. 31, 2024

Related U.S. Application Data
(63) Continuation of application No. PCT/CN2024/093311, filed on May 15, 2024.

(51) Int. Cl. G11C 11/408; G11C 11/4091; G11C 11/4097; H01L 23/528; H10B 12/00

(52) U.S. Cl. CPC G11C 11/4085; G11C 11/4091; G11C 11/4097; H01L 23/5283; H10B 12/315; H10B 12/485; H10B 12/488; H10B 12/50

(57) ABSTRACT

Methods, devices, and systems for managing layouts of semiconductor structures in memory devices are provided. In one aspect, a memory device includes a first semiconductor structure and a second semiconductor structure. The first semiconductor structure includes a first memory block, and the second semiconductor structure includes a driver circuit. The first semiconductor structure and the second semiconductor structure are stacked along a first direction. The driver circuit at least partially overlaps with the first memory block in a plan view perpendicular to the first direction.

### CROSS-REFERENCE TO RELATED APPLICATIONS

This application is a continuation of International Application No. PCT/CN2024/093311, filed on May 15, 2024, the disclosure of which is hereby incorporated by reference in its entirety.

### TECHNICAL FIELD

The present disclosure relates to semiconductor devices, e.g., memory devices.

### BACKGROUND

Semiconductor devices, e.g., memory devices, can have various structures to increase the density of memory cells and lines on a chip. A memory device normally includes a memory array of memory cells and peripheral circuits for facilitating operations of the memory array.

### SUMMARY

The present disclosure describes managing layouts of semiconductor structures in memory devices.

One aspect of the present disclosure features a memory device including a first semiconductor structure and a second semiconductor structure. The first semiconductor structure includes a first memory block, and the second semiconductor structure includes a driver circuit. The first semiconductor structure and the second semiconductor structure are stacked along a first direction (e.g., z direction). The driver circuit at least partially overlaps with the first memory block in a plan view perpendicular to the first direction.

In some implementations, the first semiconductor structure further includes a second memory block and a third memory block. Word lines coupled to memory cells of the first memory block are arranged in order. An even-numbered word line is coupled to memory cells of the second memory block, and an odd-numbered word line is coupled to memory cells of the third memory block.

In some implementations, the first memory block is positioned between the second memory block and the third memory block along a second direction (e.g., x direction) perpendicular to the first direction.

In some implementations, the second memory block is positioned adjacent to the first memory block on a first side of the first memory block, and the third memory block is positioned adjacent to the first memory block on a second side of the first memory block.

In some implementations, the driver circuit includes a first set of word line drivers and a second set of word line drivers. The even-numbered word line is coupled to a corresponding word line driver of the first set of word line drivers, and the odd-numbered word line is coupled to a corresponding word line driver of the second set of word line drivers.

In some implementations, the second semiconductor structure further includes a sensing circuit. The sensing circuit at least partially overlaps with the first memory block in the plan view.

In some implementations, the sensing circuit includes a first set of sense amplifiers and a second set of sense amplifiers. Bit lines coupled to memory strings of the first memory block are arranged in order. An even-numbered bit line is coupled to a corresponding sense amplifier of the first set of sense amplifiers, and an odd-numbered bit line is coupled to a corresponding sense amplifier of the second set of sense amplifiers.

In some implementations, the first semiconductor structure further includes a fourth memory block and a fifth memory block. A first bit line coupled to a first memory string of the fourth memory block is coupled to a corresponding sense amplifier of the first set of sense amplifiers, and a second bit line coupled to a second memory string of the fifth memory block is coupled to a corresponding sense amplifier of the second set of sense amplifiers.

In some implementations, the first memory block is positioned between the fourth memory block and the fifth memory block along a third direction (e.g., y direction) perpendicular to the first direction and the second direction.

In some implementations, the second semiconductor structure further includes a first column decoder coupled to the first set of sense amplifiers, and a second column decoder coupled to the second set of sense amplifiers. The first column decoder and the second column decoder overlap with the first memory block in the plan view.

In some implementations, the first set of word line drivers occupy a first area on the second semiconductor structure, the first set of sense amplifiers occupy a second area on the second semiconductor structure, and the first column decoder occupies a third area on the second semiconductor structure. A sum of a first length of the first area along the third direction, a second length of the second area along the third direction, and a third length of the third area along the third direction is less than or equal to a length of the first memory block along the third direction.

In some implementations, a sum of the second length and the third length is less than or equal to a half of the length of the first memory block along the third direction.

In some implementations, the memory device includes a DRAM memory device.

In some implementations, the first semiconductor structure and the second semiconductor structure include bonding contacts that bond the first semiconductor structure and the second semiconductor structure together. The bonding contacts are isolated by an isolating material.

In some implementations, the first semiconductor structure further includes a first interconnect layer positioned between the first memory block and the bonding contacts along the first direction. The first interconnect layer includes metal layers. A word line in the first memory block is connected to a respective one of the bonding contacts through at least one of the metal layers.

In some implementations, a bit line in the first memory block is connected to a respective one of the bonding contacts through at least two of the metal layers.

One aspect of the present disclosure features a method of forming a memory device. The method includes forming a first semiconductor structure based on forming a first memory block, forming a second semiconductor structure based on forming a driver circuit, and stacking the first semiconductor structure and the second semiconductor structure along a first direction. The driver circuit at least partially overlaps with the first memory block in a plan view perpendicular to the first direction.

In some implementations, the first semiconductor structure further includes a second memory block and a third memory block. Word lines coupled to memory cells of the first memory block are arranged in order. An even-numbered word line is coupled to memory cells of the second memory block, and an odd-numbered word line is coupled to memory cells of the third memory block.

In some implementations, the second memory block is positioned adjacent to the first memory block on a first side of the first memory block, and the third memory block is positioned adjacent to the first memory block on a second side of the first memory block.

In some implementations, the driver circuit includes a first set of word line drivers and a second set of word line drivers. The even-numbered word line is coupled to a corresponding word line driver of the first set of word line drivers, and the odd-numbered word line is coupled to a corresponding word line driver of the second set of word line drivers.

In some implementations, the second semiconductor structure includes a sensing circuit including a first set of sense amplifiers and a second set of sense amplifiers. The sensing circuit at least partially overlaps with the first memory block in the plan view. Bit lines coupled to memory strings of the first memory block are arranged in order. An even-numbered bit line is coupled to a corresponding sense amplifier of the first set of sense amplifiers, and an odd-numbered bit line is coupled to a corresponding sense amplifier of the second set of sense amplifiers.

One aspect of the present disclosure features a memory system. The memory system includes a memory device and a memory controller coupled to the memory device and configured to control the memory device. The memory device includes a first semiconductor structure including a first memory block and a second semiconductor structure including a driver circuit. The first semiconductor structure and the second semiconductor structure are stacked along a first direction. The driver circuit at least partially overlaps with the first memory block in a plan view perpendicular to the first direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a schematic view of a cross-section of an example memory device.

FIG. 1B illustrates a schematic view of a cross-section of another example memory device.

FIG. 2 illustrates a cross-sectional view of an example memory device.

FIG. 3 illustrates a schematic diagram of an example memory device including a peripheral circuit and an array of memory cells each having a vertical transistor.

FIG. 4 illustrates example peripheral circuits.

FIG. 5 illustrates a plan view of an example second semiconductor structure.

FIG. 6 illustrates a plan view of another example second semiconductor structure.

FIG. 7 illustrates a plan view of an example memory device having the second semiconductor structure of FIG. 6.

FIG. 8 illustrates an example memory device including example memory blocks of the first semiconductor structure and example word line drivers of the second semiconductor structure.

FIG. 9 illustrates schematic circuit diagrams of example word line drivers of FIG. 8.

FIG. 10 illustrates example word lines and example word line drivers coupled to the word lines.

FIG. 11 illustrates example metal wiring that couples word lines in a first semiconductor structure to word line drivers in a second semiconductor structure.

FIG. 12 illustrates a plan view of an example memory device having the second semiconductor structure of FIG. 6.

FIG. 13A illustrates example metal wiring that couples bit lines in a first semiconductor structure to sense amplifiers in a second semiconductor structure.

FIG. 13B illustrates example metal wiring that couples bit lines in a first semiconductor structure to sense amplifiers in a second semiconductor structure.

FIG. 14 is a flow chart of an example process of forming a memory device.

FIG. 15 illustrates a block diagram of an example system having one or more memory devices.

Like reference numbers and designations in the various drawings indicate like elements. It is also to be understood that the various exemplary implementations shown in the figures are merely illustrative representations and are not necessarily drawn to scale.

### DETAILED DESCRIPTION

As performance requirements for Dynamic Random Access Memory (DRAM) continue to escalate, the DRAM structures have evolved from 2D to 3D. Under a 2D DRAM architecture, a memory array of the DRAM device and peripheral circuits (e.g., including word line drivers, sense amplifiers, and other peripheral circuits) controlling the memory array are formed on the same wafer. Under a 3D DRAM architecture, the memory device can be a bonded memory chip including a first semiconductor structure that includes the memory array and a second semiconductor structure that includes the peripheral circuits. The first semiconductor structure and the second semiconductor structure can be formed separately on different wafers, and then stacked together to form the bonded memory chip.

Under the 3D DRAM architecture, the memory array in the first semiconductor structure can include memory blocks, and the peripheral circuits in the second semiconductor structure can include word line drivers that drive the word lines coupled to memory cells in the memory blocks. In some cases, the word line drivers are positioned outside of the memory blocks. In a plan view along a stacking direction, the word line drivers do not overlap with the memory blocks. For example, when the gap area between adjacent memory blocks in the first semiconductor structure is large, the word line drivers may only overlap with the gap area. This type of positioning of the word line drivers can be a bottleneck for improving the efficiency of the memory array and for reducing the size of the memory chip.

Implementations of the present disclosure provide techniques for managing layouts of semiconductor structures (e.g., the first semiconductor structure and the second semiconductor structure) in a memory device. In some implementations, the word line drivers are positioned under the memory blocks. That is, in the plan view along the stacking direction, the word line drivers overlap with the memory blocks, or at least partially overlap with the memory blocks.

In some implementations, the first semiconductor structure can include a first memory block, a second memory block on a first side of the first memory block along a word line direction, and a third memory block on a second side of the first memory block along the word line direction. A first group of word lines (e.g., even-numbered word lines) coupled to memory cells in the first memory block are also coupled to memory cells in the second memory block, and a second group of word lines (e.g., odd-numbered word lines) coupled to memory cells in the first memory block are also coupled to memory cells in the third memory block. In some implementations, the first group of word lines are each coupled to a corresponding word line driver of a first set of word line drivers. The second group of word lines are each coupled to a corresponding word line driver of a second set of word line drivers. In a layout of the second semiconductor structure, the first set of word line drivers can be distanced from the second set of word line drivers.

In some implementations, a first group of bit lines (e.g., even-numbered bit lines) coupled to memory strings in the first memory block are each coupled to a corresponding sense amplifier of a first set of sense amplifiers. A second group of bit lines (e.g., odd-numbered bit lines) coupled to memory strings in the first memory block are each coupled to a corresponding sense amplifier of a second set of sense amplifiers. In the layout of the second semiconductor structure, the first set of sense amplifiers can be distanced from the second set of sense amplifiers.

Implementations of the present disclosure can provide one or more of the following technical advantages. For example, by positioning the word line drivers of the second semiconductor structure under the memory blocks of the first semiconductor structure, the gap area between the memory blocks can be reduced, which increases the memory cell density of the first semiconductor structure. Moreover, the techniques of the present disclosure do not require reducing pitches and spacings between word lines or bit lines, nor require compressing process node when fabricating the first and second semiconductor structures. Therefore, the techniques of the present disclosure can improve efficiency and reduce the size of a memory chip in a cost-efficient way.

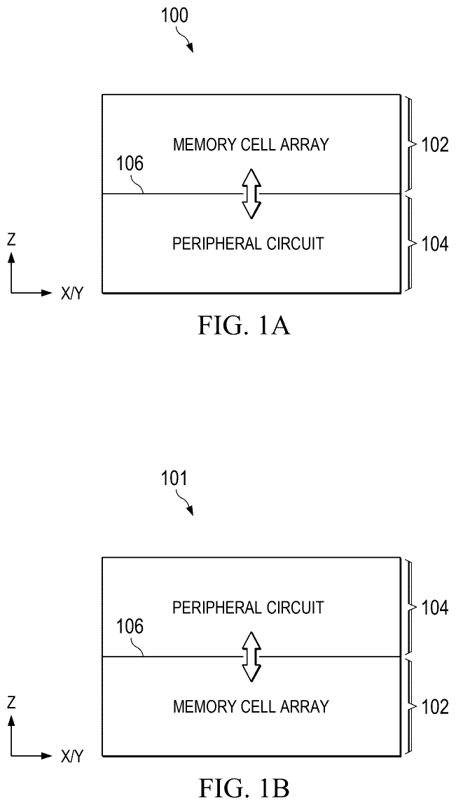

FIG. 1A illustrates a schematic view of a cross-section of a memory device 100, according to some aspects of the present disclosure. The memory device 100 represents an example of a bonded chip. The components of the memory device 100 (e.g., memory cell array and peripheral circuits) can be formed separately on different substrates and then joined to form a bonded chip. The memory device 100 can include a first semiconductor structure 102 including memory cell array. The memory device 100 can also include a second semiconductor structure 104 including peripheral circuits. The peripheral circuits (e.g., control and sensing circuits) can include any suitable digital, analog, and/or mixed-signal circuits used for facilitating the operations of the memory cell array. For example, the peripheral circuits can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a subcircuit) of the functional circuits mentioned above, or any active or passive components of the circuit (e.g., transistors, diodes, resistors, or capacitors). The peripheral circuits in the second semiconductor structure 104 use complementary metal-oxide-semiconductor (CMOS) technology, which can be implemented, for example, with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

As shown in FIG. 1A, the memory device 100 can also include the first semiconductor structure 102 including an array of memory cells (memory cell array) that can use transistors as the switch and selecting devices. In some implementations, the memory cell array includes an array of DRAM cells. For ease of description, a DRAM cell array may be used as an example for describing the memory cell array in the present disclosure. But it is understood that the memory cell array is not limited to DRAM cell array and may include any other suitable types of memory cell arrays that can use transistors as the switch and selecting devices, such as PCM cell array, static random-access memory (SRAM) cell array, FRAM cell array, resistive memory cell array, magnetic memory cell array, spin transfer torque (STT) memory cell array, to name a few, or any combination thereof.

The first semiconductor structure 102 can be a DRAM device in which memory cells are provided in the form of an array of DRAM cells. In some implementations, each DRAM cell includes a capacitor for storing a bit of data as a positive or negative electrical charge as well as one or more transistors (e.g., pass transistors) that control (e.g., switch and select) access to it. In some implementations, each DRAM cell is a one-transistor, one-capacitor (1TIC) cell. Since transistors can leak a small amount of charge, the capacitors can slowly discharge, causing information stored in them to drain. As such, a DRAM cell can be refreshed to retain data, for example, by the peripheral circuit in the second semiconductor structure 104, according to some implementations.

As shown in FIG. 1A, the memory device 100 further includes a bonding interface 106 vertically between (in the vertical direction, e.g., the z-direction in FIG. 1A) the first semiconductor structure 102 and the second semiconductor structure 104. As described below in detail, the first and second semiconductor structures 102 and 104 can be fabricated separately (and in parallel in some implementations) such that the thermal budget of fabricating one of the first and second semiconductor structures 102 and 104 does not limit the processes of fabricating another one of the first and second semiconductor structures 102 and 104. Moreover, a large number of interconnects (e.g., bonding contacts) can be formed through the bonding interface 106 to make direct, short-distance (e.g., micron-level) electrical connections between first semiconductor structure 102 and second semiconductor structure 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory cell array in first semiconductor structure 102 and the peripheral circuits in second semiconductor structure 104 can be performed through the interconnects (e.g., bonding contacts) across the bonding interface 106. By vertically integrating the first and second semiconductor structures 102 and 104, the chip size can be reduced, and the memory cell density can be increased.

It is understood that the relative positions of stacked first and second semiconductor structures 102 and 104 are not limited. FIG. 1B illustrates a schematic view of a cross-section of another memory device 101, according to some aspects of the present disclosure. Different from the memory device 100 in FIG. 1A in which the first semiconductor structure 102 including the memory cell array is above the second semiconductor structure 104 including the peripheral circuits, in the memory device 101 in FIG. 1B, the second semiconductor structure 104 including the peripheral circuit is above the first semiconductor structure 102 including the memory cell array. Nevertheless, the bonding interface 106 is formed vertically between the first and second semiconductor structures 102 and 104 in the memory device 101, and the first and second semiconductor structures 102 and 104 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously. Data transfer between the memory cell array in the first semiconductor structure 102 and the peripheral circuits in the second semiconductor structure 104 can be performed through the interconnects (e.g., bonding contacts) across bonding interface 106.

It is noted that x, y, and z axes are included in FIGS. 1A and 1B to further illustrate the spatial relationship of the components in memory devices 100 and 101. The substrate of the memory device includes two lateral surfaces extending laterally in the x-y plane: a top surface on the front side of the wafer on which the semiconductor devices can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of the memory device is determined relative to the substrate of the memory device in the z-direction (the vertical direction perpendicular to the x-y plane, e.g., the thickness direction of the substrate) when the substrate is positioned in the lowest plane of the memory device in the z-direction. The same notion for describing the spatial relationships is applied throughout the present disclosure.

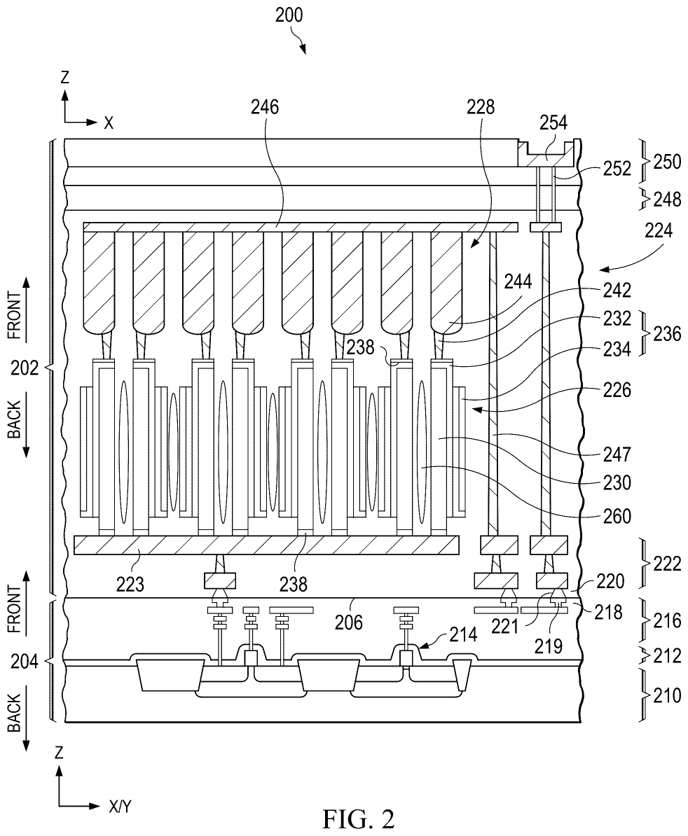

FIG. 2 illustrates a side view of a cross-section of an example memory device 200, according to some aspects of the present disclosure. The memory device 200 can be a dynamic random-access memory (DRAM). In some implementations, the memory device 200 is a bonded chip including a first semiconductor structure 202 (e.g., the first semiconductor structure 102 of FIGS. 1A-1B) and a second semiconductor structure 204 (e.g., the second semiconductor structure 104 of FIGS. 1A-1B). The first semiconductor structure 202 can be stacked over the second semiconductor structure 204. The first and second semiconductor structures 202 and 204 can be jointed at a bonding interface 206 therebetween.

As shown in FIG. 2, the second semiconductor structure 204 can include a substrate 210, which can include silicon (e.g., single crystalline silicon, c-Si), SiGe, GaAs, Ge, SOI, or any other suitable materials. The second semiconductor structure 204 can include peripheral circuits 212 on and/or in the substrate 210. In some implementations, the peripheral circuits 212 include a plurality of transistors 214 (e.g., planar transistors and/or 3D transistors). Trench isolations (e.g., shallow trench isolations (STIs)) and doped regions (e.g., wells, sources, and drains of transistors 214) can be formed on or in the substrate 210 as well. In some examples, the peripheral circuits 212 are formed using complementary metal-oxide-semiconductor (CMOS) technology, and the second semiconductor structure 204 can be also formed on a semiconductor die that can be referred to as a control die or a CMOS die 204.

In some implementations, the second semiconductor structure 204 further includes an interconnect layer 216 above the peripheral circuits 212 to transfer electrical signals to and from the peripheral circuits 212. The interconnect layer 216 can include a plurality of interconnects (also referred to herein as “contacts”), including lateral interconnect lines and VIA contacts. The interconnect layer 216 can include one or more metal layers separated by interlay dielectric (ILD) layers. The interconnect lines and via contacts can form in the ILD layer to form electric contact between different metal layers. That is, the interconnect layer 216 can include interconnect lines and via contacts in multiple ILD layers. In some implementations, peripheral circuits 212 are coupled to one another through the interconnects in the interconnect layer 216. The interconnects in interconnect layer 216 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 2, the second semiconductor structure 204 has a front side and a back side, and the second semiconductor structure 204 can further include a bonding layer 218 at the back side at the bonding interface 206 and above the interconnect layer 216 and the peripheral circuits 212. The bonding layer 218 can include a plurality of bonding contacts 219 and dielectrics electrically isolating the bonding contacts 219. The bonding contacts 219 can include conductive materials, such as Cu. The remaining area of the bonding layer 218 can be formed with dielectric materials, such as silicon oxide. The bonding contacts 219 and surrounding dielectrics in the bonding layer 218 can be used for hybrid bonding. Similarly, as shown in FIG. 2, the first semiconductor structure 202 can also include a bonding layer 220 at the bonding interface 206 and above the bonding layer 218 of the second semiconductor structure 204. The bonding layer 220 can include a plurality of bonding contacts 221 and dielectrics electrically isolating the bonding contacts 221. The bonding contacts 221 can include conductive materials, such as Cu. The remaining area of the bonding layer 220 can be formed with dielectric materials, such as silicon oxide. The bonding contacts 221 and surrounding dielectrics in the bonding layer 220 can be used for hybrid bonding. The bonding contacts 221 can be in contact with the bonding contacts 219 at the bonding interface 206. In some implementations, the bonding layer 220 includes a dielectric layer opposing memory cells (e.g., DRAM cells) 224 with a bit line 223 positioned between the dielectric layer and the memory cells 224, as shown in FIG. 2. The dielectric layer can include the bonding interface 206 having the bonding contacts 221.

The first semiconductor structure 202 can be bonded on top of the second semiconductor structure 204 in a face-to-face manner at the bonding interface 206. In some implementations, the bonding interface 206 is disposed between the bonding layers 220 and 218 as a result of hybrid bonding. In some implementations, the bonding interface 206 is the place at which bonding layers 220 and 218 are met and bonded. In some examples, the bonding interface 206 can be a layer with a certain thickness that includes the top surface of the bonding layer 218 of the second semiconductor structure 204 and the bottom surface of the bonding layer 220 of the first semiconductor structure 202.

In some implementations, the first semiconductor structure 202 further includes an interconnect layer 222 including bit lines 223 above the bonding layer 220 to transfer electrical signals. The interconnect layer 222 can include a plurality of interconnects, such as mid end of line (MEOL) interconnects and back end of line (BEOL) interconnects. In some implementations, the interconnects in interconnect layer 222 also include local interconnects, such as the bit lines 223 and word line contacts (not shown). The interconnect layer 222 can include one or more metal layers separated by interlay dielectric (ILD) layers. The interconnect lines and via contacts can form in the ILD layers to form electric contact between different metal layers. The interconnects in the interconnect layer 222 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 212 include a word line driver/row decoder coupled to the word line contacts in the interconnect layer 222 through the bonding contacts 221 and 219 in the bonding layers 220 and 218 and the interconnect layer 216. In some implementations, the peripheral circuits 212 include a bit line driver/column decoder coupled to the bit lines 223 and bit line contacts in the interconnect layer 222 through the bonding contacts 221 and 219 in the bonding layers 220 and 218 and the interconnect layer 216. In some implementations, the bit line 223 is a metal bit line, as opposed to semiconductor bit lines (e.g., doped silicon bit lines). For example, the bit line 223 may include W, Co, Cu, Al, or any other suitable metals having higher conductivities than doped silicon. In some implementations, the bit line contact is an ohmic contact as opposed to a Schottky contact.

In some implementations, the bit line 223 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the first semiconductor structure 202 includes DRAM cells 224 provided in the form of a memory cell array above the interconnect layer 222 and the bonding layer 220. That is, the interconnect layer 222 including the bit lines 223 can be disposed between bonding layer 220 and array of DRAM cells 224. A bit line 223 in the interconnect layer 222 can be coupled to a string of DRAM cells 224. In some implementations, the first semiconductor structure 202 is formed on a semiconductor die and can be referred to as array die 202.

In some implementations, a semiconductor device can include multiple array dies (e.g., the array die 202) and a CMOS die (e.g., the CMOS die 204). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together. As such, the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 224 can include a vertical transistor 226 and a capacitor 228 coupled to the vertical transistor 226. DRAM cell 224 can be a 1TIC cell consisting of one transistor and one capacitor. It is understood that DRAM cell 224 may be of any suitable configurations, such as 2T1C cell, 3T1C cell, etc. The vertical transistor 226 can be a MOSFET used to switch a respective DRAM cell 224. In some implementations, the vertical transistor 226 includes a semiconductor body 230 (the active region in which a channel can form) extending vertically (in the z-direction), and a gate structure 236 in contact with one side of semiconductor body 230. In a single-gate vertical transistor, the semiconductor body 230 can have a cuboid shape or a cylinder shape, and the gate structure 236 can abut a single side of semiconductor body 230 in a plane view, e.g., as shown in FIG. 2. In some implementations, the vertical transistor 226 has a structure including two or more gates, e.g., a two-gates structure, a three-gates structure, or a gate all around (GAA) structure. In some implementations, the gate structure 236 includes a gate electrode 234 and a gate dielectric 232 laterally between the gate electrode 234 and the semiconductor body 230 in a bit line direction (e.g., in the Y direction). In some implementations, the gate dielectric 232 abuts one side of the semiconductor body 230, and the gate electrode 234 abuts the gate dielectric 232.

As shown in FIG. 2, in some implementations, the semiconductor body 230 has two ends (the upper end and lower end in FIG. 2) in the vertical direction (the z-direction), and at least one end (e.g., the lower end) extends beyond gate dielectric 232 in the vertical direction (the z-direction) into the ILD layers. In some implementations, one end (e.g., the upper end) of the semiconductor body 230 is flush with the respective end (e.g., the upper end) of the gate dielectric 232. In some implementations, both ends (the upper end and lower end) of the semiconductor body 230 extend beyond the gate electrode 234, respectively, in the vertical direction (the z-direction) into ILD layers. That is, the semiconductor body 230 can have a larger vertical dimension (e.g., the depth) than that of the gate electrode 234 (e.g., in the z-direction), and neither the upper end nor the lower end of semiconductor body 230 is flush with the respective end of the gate electrode 234. Thus, short circuits between the bit lines 223 and the word lines 235 or between the word lines 235 and the capacitors 228 can be avoided. The vertical transistor 226 can further include a source and a drain (both referred to as 238 as their locations may be interchangeable) disposed at the two ends (the upper end and lower end) of the semiconductor body 230, respectively, in the vertical direction (the z-direction). In some implementations, one of the source or drain 238 (e.g., at the upper end in FIG. 2) is coupled to the capacitor 228, and the other one of source and drain 238 (e.g., at the lower end in FIG. 2) is coupled to the bit line 223. That is, the vertical transistor 226 can have a first terminal in the positive z-direction and a second terminal opposite the first terminal in the negative z-direction, as shown in FIG. 2.

In some implementations, the semiconductor body 230 includes semiconductor materials, such as single crystalline silicon, polysilicon, amorphous silicon, Ge, any other semiconductor materials, or any combinations thereof. In one example, semiconductor body 230 may include single crystalline silicon. Source and drain 238 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between source/drain 238 of the vertical transistor 226 and the bit line 223 as the bit line contact or between source/drain 238 of the vertical transistor 226 and the first electrode of the capacitor 228 as capacitor contact 242 to reduce the contact resistance. In some implementations, gate dielectric 232 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 234 includes a conductive material including, but not limited to W, Co, Cu, Al, TiN, TaN, polysilicon, silicide, or any combination thereof. In some implementations, the gate electrode 234 includes multiple conductive layers, such as a W layer over a TiN layer. In one example, the gate structure 236 may be a “gate oxide/gate poly” gate in which the gate dielectric 232 includes silicon oxide and gate electrode 234 includes doped polysilicon. In another example, gate structure 236 may be an HKMG in which gate dielectric 232 includes a high-k dielectric and gate electrode 234 includes a metal.

As described above, since the gate electrode 234 may be part of a word line or extend in the word line direction (e.g., the X direction) as a word line, the first semiconductor structure 202 of the memory device 200 can also include a plurality of word lines each extending in the word line direction. Each word line 235 can be coupled to a row of DRAM cells 224. That is, the bit line 223 and the word line 235 can extend in two perpendicular lateral directions, and the semiconductor body 230 of the vertical transistor 226 can extend in the vertical direction perpendicular to the two lateral directions in which the bit line 223 and the word line 235 extend. Word lines 235 are in contact with word line contacts (not shown). In some implementations, the word lines 235 include conductive materials including, but not limited to W, Co, Cu, Al, TiN, TaN, polysilicon, silicides, or any combination thereof. In some implementations, the word line 235 includes multiple conductive layers, such as a W layer over a TiN layer.

In some implementations, the vertical transistor 226 extends vertically through and contacts the word lines 235, and the source or drain 238 of vertical transistor 226 at the lower end thereof is in contact with the bit line 223 (or bit line contact if any). Accordingly, the word lines 235 and the bit lines 223 can be disposed in different planes in the vertical direction due to the vertical arrangement of vertical transistor 226, which simplifies the routing of the word lines 235 and the bit lines 223. In some implementations, the bit lines 223 are disposed vertically between the bonding layer 220 and the word lines 235, and the word lines 235 are disposed vertically between the bit lines 223 and the capacitors 228. The word lines 235 can be coupled to the peripheral circuits 212 in the second semiconductor structure 204 through word line contacts (not shown) in the interconnect layer 222, the bonding contacts 221 and 219 in the bonding layers 220 and 218, and the interconnects in the interconnect layer 216. Similarly, the bit lines 223 in the interconnect layer 222 can be coupled to the peripheral circuits 212 in the second semiconductor structure 204 through the bonding contacts 221 and 219 in the bonding layers 220 and 218 and the interconnects in the interconnect layer 216.

In some implementations, the vertical transistors 226 can be arranged in a mirror-symmetric manner to increase the density of DRAM cells 224 in the bit line direction (the Y direction). As shown in FIG. 2, two adjacent vertical transistors 226 in the bit line direction are mirror-symmetric to one another with respect to a trench isolation 260. That is, the first semiconductor structure 202 can include a plurality of trench isolations 260 each extending in the word line direction (the X direction) in parallel with word lines 235 and disposed between vertical gate electrodes 234 of two adjacent rows of the vertical transistors 226. In some implementations, the rows of vertical transistors 226 separated by the trench isolation 260 are mirror-symmetric to one another with respect to the trench isolation 260. The trench isolation 260 can be formed with dielectric materials including, but not limited to, silicon oxide, silicon nitride, silicon oxynitride, low-k dielectrics, or any combination thereof. It is understood that the trench isolation 260 may include an air gap each disposed laterally between adjacent vertical gate electrodes 234. Air gaps may be formed due to the relatively small pitches of vertical transistors 226 in the bit line direction (e.g., the Y direction). On the other hand, the relatively large dielectric constant of air in air gaps (e.g., about 4 times of the dielectric constant of silicon oxide) can improve the insulation effect between vertical transistors 226 (and rows of DRAM cells 224) compared with some dielectrics (e.g., silicon oxide). Similarly, in some implementations, air gaps are formed laterally between word lines 235 in the bit line direction as well, depending on the pitches of word lines 235 in the bit line direction. In some implementations, instead of the trench isolation 260 having the air gap being disposed between adjacent vertical gate electrodes 234 of two adjacent rows of the vertical transistors 226, a conductive structure (e.g., including metal such as W) is disposed between adjacent semiconductor bodies 230 of two adjacent rows of vertical transistors 226.

In some implementations, a capacitor 228 includes a first electrode 244 above and coupled to the source or drain 238 of vertical transistor 226, e.g., the upper end of the semiconductor body 230, via a capacitor contact 242. In some implementations, the capacitor contact 242 is an ohmic contact, such as a metal silicide contact, as opposed to a Schottky contact. For example, the capacitor contact 242 may include metal silicides, such as WSi, CoSi, CuSi, AlSi, or any other suitable metal silicides having higher conductivities than doped silicon. The capacitor 228 can also include a capacitor dielectric above and in contact with the first electrode 244, and a second electrode above and in contact with the capacitor dielectric. That is, the capacitor 228 can be a vertical capacitor in which the electrodes and capacitor dielectric are stacked vertically (in the z-direction), and the capacitor dielectric can be sandwiched between the electrodes. In some implementations, each first electrode is coupled to source or drain 238 of a respective vertical transistor 226 in the same DRAM cell, while all second electrodes are coupled to a common plate 246 coupled to the ground, e.g., a common ground. The capacitor 228 can have a first end in the negative z-direction and a second end opposite the first end in the positive z-direction, as shown in FIG. 2. In some implementations, the first end of the capacitor 228 is coupled to the first terminal of the vertical transistor 226 via an ohmic contact (e.g., the capacitor contact 242 made of a metal silicide material). As shown in FIG. 2, the first semiconductor structure 202 can further include a capacitor contact 247 (e.g., a conductor) in contact with a common plate 246 for coupling the capacitors 228 to the peripheral circuits 212 or to the ground directly. In some implementations, the capacitor contact 247 (e.g., a conductor) extends in the z-direction from the dielectric layer of the bonding layer 220 to couple to the second end of the capacitor 228 via the common plate 246, as shown in FIG. 2. In some implementations, the ILD layer in which the capacitors 228 are formed has the same dielectric material as the two ILD layers into which the semiconductor body 230 extends, such as silicon oxide.

It is understood that the structure and configuration of a capacitor 228 are not limited to the example in FIG. 2 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 228 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 2, vertical transistor 226 extends vertically through and contacts the word lines 235, source or drain 238 of vertical transistor 226 at the lower end thereof is in contact with the bit line 223, and source or drain 238 of vertical transistor 226 at the upper end thereof is coupled to the capacitor 228. That is, the bit line 223 and the capacitor 228 can be disposed in different planes in the vertical direction and coupled to opposite ends of vertical transistor 226 of DRAM cell 224 in the vertical direction due to the vertical arrangement of vertical transistor 226. In some implementations, the bit line 223 and the capacitor 228 are disposed on opposite sides of the vertical transistor 226 in the vertical direction, which simplifies the routing of the bit lines 223 and reduces the coupling capacitance between the bit lines 223 and the capacitors 228 compared with DRAM cells in which the bit lines and capacitors are disposed on the same side of the planar transistors.

As shown in FIG. 2, in some implementations, the vertical transistors 226 are disposed vertically between the capacitors 228 and the bonding interface 206. That is, the vertical transistors 226 can be arranged closer to the peripheral circuits 212 of the second semiconductor structure 204 and the bonding interface 206 than the capacitors 228. Since the bit lines 223 and the capacitors 228 are coupled to opposite ends of the vertical transistors 226, the bit lines 223 (as part of the interconnect layer 222) are disposed vertically between the vertical transistors 226 and the bonding interface 206 As a result, the interconnect layer 222 including bit lines 223 can be arranged close to the bonding interface 206 to reduce the interconnect routing distance and complexity.

In some implementations, the first semiconductor structure 202 further includes a substrate 248 disposed above the DRAM cells 224. The substrate 248 can be part of a carrier wafer. It is understood that in some examples, the substrate 248 may not be included in the first semiconductor structure 202.

In some implementations, the first semiconductor structure 202 can further include a pad-out interconnect layer 250 above the substrate 248 and the DRAM cells 224. The pad-out interconnect layer 250 can include interconnects, e.g., contact pads 254, in one or more ILD layers. The pad-out interconnect layer 250 and the interconnect layer 222 can be formed on opposite sides of the DRAM cells 224. The capacitors 228 can be disposed vertically between the vertical transistors 226 and the pad-out interconnect layer 250. In some implementations, the interconnects in pad-out interconnect layer 250 can transfer electrical signals between the memory device 200 and outside circuits, e.g., for pad-out purposes.

In some implementations, the first semiconductor structure 202 further includes one or more contacts 252 extending through the substrate 248 and part of the pad-out interconnect layer 250 to couple the pad-out interconnect layer 250 to the DRAM cells 224 and the interconnect layer 222. As a result, the peripheral circuits 212 can be coupled to the DRAM cells 224 through the interconnect layers 216 and 222 as well as the bonding layers 220 and 218, and the peripheral circuits 212 and the DRAM cells 224 can be coupled to outside circuits through contacts 252 and pad-out interconnect layer 250. Contact pads 254 and contacts 252 can include conductive materials including, but not limited to, W, Co, Cu, Al, silicides, or any combination thereof. In one example, the contact pad 254 may include Al, and the contact 252 may include W. In some implementations, the contact 252 includes a via surrounded by a dielectric spacer (e.g., having silicon oxide) to electrically separate the via from substrate 248. Depending on the thickness of substrate 248, contact 252 can be an ILV having a depth in the submicron level (e.g., between 20 nm and 1 μm), or a TSV having a depth in the micron-or tens micron-level (e.g., between 1 μm and 200 μm).

Although not shown, it is understood that the pad-out of memory devices is not limited to from the first semiconductor structure 202 having DRAM cells 224 as shown in FIG. 2 and may be from the second semiconductor structure 204 having peripheral circuit 212. Although not shown, it is also understood that the air gaps between word lines 235 and/or between semiconductor bodies 230 may be partially or fully filled with dielectrics. Although not shown, it is further understood that more than one array of DRAM cells 224 may be stacked over one another to vertically scale up the number of DRAM cells 224.

In some implementations, instead of having the substrate 248 above the DRAM cells 224 as shown in FIG. 2, the first semiconductor structure 202 includes a substrate disposed below the DRAM cells 224. The substrate can be part of a carrier wafer. The DRAM cells 224 can be formed in a front side of the substrate, and the bit lines 223 can be formed in a back side of the substrate. The bit lines 223 can be conductively coupled to the DRAM cells 224 (e.g., the source/drain 238 of the vertical transistors 226) through the substrate.

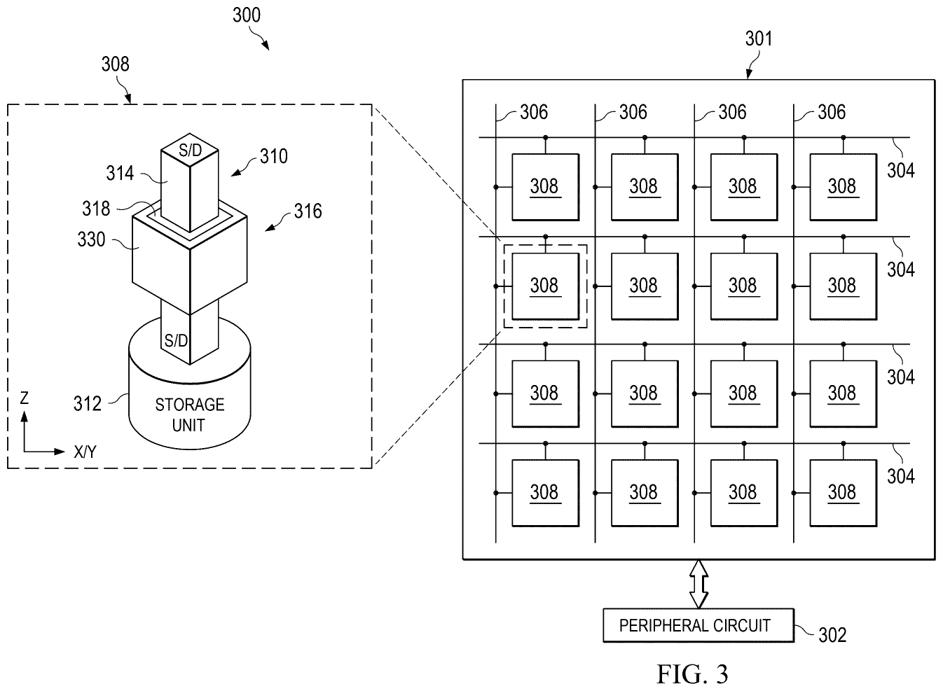

FIG. 3 illustrates a schematic diagram of a memory device 300 including peripheral circuits and an array of memory cells each having a vertical transistor, according to some aspects of the present disclosure. The memory device 300 can include a memory array 301 and peripheral circuits 302 coupled to memory array 301. With reference to FIGS. 1A-1B and FIG. 2, memory devices 100, 101, 200 may be examples of the memory device 300 in which memory array 301 and peripheral circuits 302 may be included in the first and second semiconductor structures 102 and 104, respectively. The memory array 301 can be any suitable memory cell array in which each memory cell 308 includes a vertical transistor 310 and a storage unit 312 coupled to vertical transistor 310. In some implementations, the memory array 301 is a DRAM cell array, and the storage unit 312 is a capacitor for storing charge as the binary information stored by the respective DRAM cell. In some implementations, the memory array 301 is a PCM cell array, and storage unit 312 is a PCM element (e.g., including chalcogenide alloys) for storing binary information of the respective PCM cell based on the different resistivities of the PCM element in the amorphous phase and the crystalline phase. In some implementations, the memory array 301 is a FRAM cell array, and the storage unit 312 is a ferroelectric capacitor for storing binary information of the respective FRAM cell based on the switch between two polarization states of ferroelectric materials under an external electric field.

As shown in FIG. 3, memory cells 308 can be arranged in a two-dimensional (2D) array having rows and columns. Memory device 300 can include word lines 304 coupling peripheral circuits 302 and memory array 301 for controlling the switch of vertical transistors 310 in memory cells 308 located in a row, as well as bit lines 306 coupling peripheral circuits 302 and memory array 301 for sending data to and/or receiving data from memory cells 308 located in a column. That is, each word line 304 is coupled to a respective row of memory cells 308, and each bit line is coupled to a respective column of memory cells 308 (e.g., a string of memory cells 308).

In some implementations, a memory cell 308 can include a vertical transistor 310, such as a vertical metal-oxide-semiconductor field-effect transistor (MOSFET), instead of a planar transistor as a pass transistor, to reduce the area occupied by the pass transistors of the memory cells 308, reduce the coupling capacitance, as well as reduce the interconnect routing complexity. As shown in FIG. 3, in some implementations, different from planar transistors in which the active regions are formed in the substrates, vertical transistor 310 includes a semiconductor body 314 extending vertically (in the z direction) above the substrate (not shown). That is, semiconductor body 314 can extend above the top surface of the substrate to expose not only the top surface of semiconductor body 314, but also one or more side surfaces thereof. As shown in FIG. 3, for example, semiconductor body 314 can have a cuboid shape to expose four sides thereof. It is understood that semiconductor body 314 may have any suitable 3D shape, such as polyhedron shapes or a cylinder shape. That is, the cross-section of semiconductor body 314 in the plan view (e.g., in the x-y plane) can have a square shape, a rectangular shape (or a trapezoidal shape), a circular (or an oval shape), or any other suitable shapes.

As shown in FIG. 3, vertical transistor 310 can also include a gate structure 316 in contact with one or more sides of semiconductor body 314, i.e., in one or more planes of the side surface(s) of the active region. In other words, the active region of vertical transistor 310, i.e., semiconductor body 314, can be at least partially surrounded by gate structure 316. Gate structure 316 can include a gate dielectric 318 over one or more sides of semiconductor body 314, e.g., in contact with four side surfaces of semiconductor body 314 as shown in FIG. 3. Gate structure 316 can also include a gate electrode 320 over and in contact with gate dielectric 318. Gate dielectric 318 can include any suitable dielectric materials, such as silicon oxide, silicon nitride, silicon oxynitride, or high-k dielectrics. For example, gate dielectric 318 may include silicon oxide, i.e., gate oxide. Gate electrode 320 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 320 may include doped polysilicon, i.e., a gate poly. In some implementations, gate electrode 320 includes multiple conductive layers, such as a W layer over a TiN layer. It is understood that gate electrode 320 and word line 304 may be a continuous conductive structure in some examples. In other words, gate electrode 320 may be viewed as part of word line 304 that forms gate structure 316, or word line 304 may be viewed as the extension of gate electrode 320 to be coupled to peripheral circuits 302.

As shown in FIG. 3, vertical transistor 310 can further include a pair of a source and a drain (SID, dope regions, a.k.a., source electrode and drain electrode) formed at the two ends of semiconductor body 314 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 316 in the vertical direction (the z-direction). In other words, gate structure 316 is formed vertically between the source and drain. As a result, one or more channels (not shown) of vertical transistor 310 can be formed in semiconductor body 314 vertically between the source and drain when a gate voltage applied to gate electrode 320 of gate structure 316 is above the threshold voltage of vertical transistor 310. That is, each channel of vertical transistors 310 is also formed in the vertical direction along which semiconductor body 314 extends, according to some implementations.

In some implementations, as shown in FIG. 3, vertical transistor 310 is a multi-gate transistor. That is, gate structure 316 can be in contact with more than one side of semiconductor body 314 (e.g., four sides in FIG. 3) to form more than one gate, such that more than one channel can be formed between the source and drain in operation. That is, different from the planar transistor that includes only a single planar gate (and resulting in a single planar channel), vertical transistor 310 shown in FIG. 3 can include multiple vertical gates on multiple sides of semiconductor body 314 due to the 3D structure of semiconductor body 314 and gate structure 316 that surrounds the multiple sides of semiconductor body 314. As a result, compared with planar transistors, vertical transistor 310 shown in FIG. 3 can have a larger gate control area to achieve better channel control with a smaller subthreshold swing. During the off state, since the channel is fully depleted, the leakage current of vertical transistor 310 can be significantly reduced as well. The multi-gate vertical transistors can include double-gate vertical transistors (e.g., dual-side gate vertical transistors), tri-gate vertical transistors (e.g., tri-side gate vertical transistors), and GAA vertical transistors.

It is understood that although vertical transistor 310 is shown as a multi-gate transistor in FIG. 3, the vertical transistors disclosed herein may also include single-gate transistors as described below in detail. That is, gate structure 316 may be in contact with a single side of semiconductor body 314, for example, for the purpose of increasing the transistor and memory cell density. It is also understood that although gate dielectric 318 is shown as being separate (i.e., a separate structure) from other gate dielectrics of adjacent vertical transistors (not shown), gate dielectric 318 may be part of a continuous dielectric layer having multiple gate dielectrics of vertical transistors.

In planar transistors and some lateral multiple-gate transistors (e.g., FinFET), the active regions, such as semiconductor bodies (e.g., Fins), extend laterally (in the x-y plane), and the source and the drain are disposed at different locations in the same lateral plane (the x-y plane). In contrast, in vertical transistor 310, semiconductor body 314 extends vertically (in the z-direction), and the source and the drain are disposed in the different lateral planes, according to some implementations. In some implementations, the source and the drain are formed at two ends of semiconductor body 314 in the vertical direction (the z direction), respectively, thereby being overlapped in the plan view. As a result, the area (in the x-y plane) occupied by vertical transistor 310 can be reduced compared with planar transistor and lateral multiple-gate transistors. Also, the metal wiring coupled to vertical transistors 310 can be simplified since the interconnects can be routed in different planes. For example, bit lines 306 and storage units 312 may be formed on opposite sides of vertical transistor 310. In one example, bit line 306 may be coupled to the source or the drain at the upper end of semiconductor body 314, while storage unit 312 may be coupled to the other source or the drain at the lower end of semiconductor body 314.

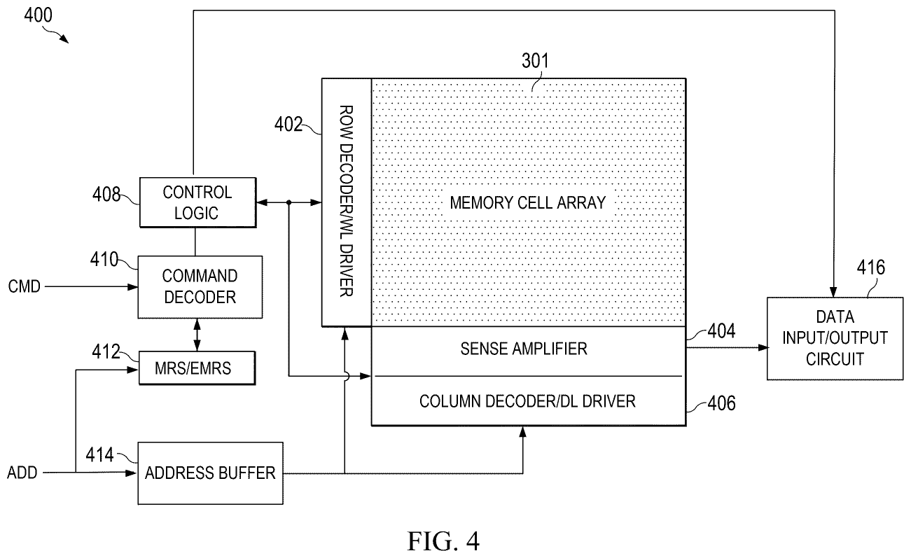

FIG. 4 illustrates example peripheral circuits 302, according to some aspects of the present disclosure. The peripheral circuits 302 can be coupled to the memory array 301 through bit lines 306 and word lines 304. The peripheral circuits 302 can include any suitable analog, digital, and mixed-signal circuits for facilitating the operations of the memory array 301. The peripheral circuits 302 can include various types of peripheral circuits formed using metal-oxide-semiconductor (MOS) technologies. The example peripheral circuits include a row decoder/word line driver 402, a sense amplifier 404, a column decoder/data line driver 406, control logic 408, a command decoder 410, a mode register set/extended mode register set (MRS/EMRS) circuit 412, an address buffer 414, and a data input/output circuit 416. In some examples, additional peripheral circuits not shown in FIG. 3 may be included as well.

The sense amplifier 404 can sense and amplify data of a memory cell and can store data in the memory cell. The sense amplifier 404 can be implemented by a cross-coupled amplifier connected between a bit line and a complementary bit line, which are included in the memory array 301.

The data input/output circuit 416 can write input data to the memory array 301 based on an address signal (ADD), and can read output data from the memory array 301 based on address signal (ADD) and output the data to the outside of the memory device 400. To designate a memory cell for data to be written to or to be read from, the address signal (ADD) can be input to the address buffer 414, which can temporarily store the address signal (ADD).

The row decoder/word line driver 402 can decode a row address in the address signal (ADD) output from the address buffer 414, to designate a word line connected to a memory cell for data to be written to or to be read from. For example, in a data write or read mode, the row decoder/word line driver 402 can decode a row address output from the address buffer 414 and thus enable a word line corresponding to the row address. In addition, in a self-refresh mode, the row decoder/word line driver 402 can decode a row address generated by an address counter and thus enable a word line corresponding to the row address.

The column decoder/data line driver 406 can decode a column address in the address signal (ADD), which is output from the address buffer 414, to designate a bit line connected to a memory cell for data to be written to or to be read from. The memory array 301 can read data from or write data to a memory cell designated by the row and column addresses.

The command decoder 410 can receive a command signal (CMD) from a host or a memory controller, and can internally generate a decoded command signal by decoding such signals.

The MRS/EMRS circuit 412 can set a mode register in response to an MRS/EMRS command for designating an operation mode of the memory device 400.

The peripheral circuits may further include a clock circuit for generating a clock signal, a power supply circuit generating or distributing internal voltages by receiving power supply voltages applied from outside thereof, or the like.

The control logic 408 can be coupled to each peripheral circuit described above and configured to control operations of each peripheral circuit.

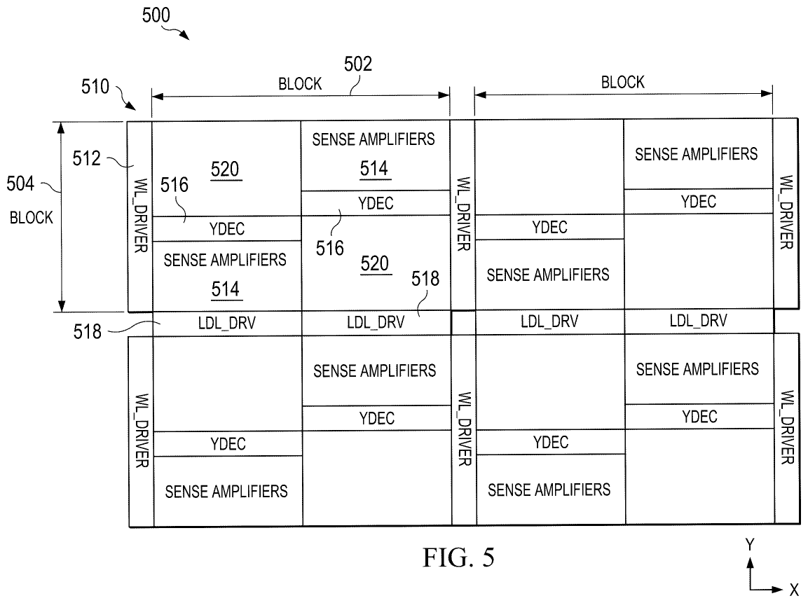

FIG. 5 illustrates a plan view (e.g., in the XY plane) of an example second semiconductor structure 500 (e.g., the second semiconductor structure 104 in FIGS. 1A and 1B), according to one or more implementations of the present disclosure. A width 502 represents a width (e.g., along x direction) of a memory block of the first semiconductor structure (e.g., the first semiconductor structure 102 of FIGS. 1A and 1B) that is coupled to a corresponding set of control circuits of the second semiconductor structure. For example, each set of control circuits is stacked with a corresponding memory block along the vertical direction (e.g., z direction). A length 504 represents the length (e.g., along y direction) of the memory block. As shown in FIG. 5, the second semiconductor structure 500 can include four sets of control circuits (e.g., including some of the peripheral circuits as shown in FIG. 4) that are stacked with four adjacent memory blocks. The second semiconductor structure 500 can include other number of sets of control circuits. For ease of explanation, a first set of control circuits 510 is described in detail, and the remaining sets of control circuits can be the same or substantially similar to the first set of control circuits 510.

As shown in FIG. 5, the first set of control circuits can include a driver circuit including word line drivers 512, a sensing circuit including sense amplifiers 514, column decoder 516, and remaining circuits 520. Each word line driver is coupled to a word line in the first semiconductor structure, where the word line is coupled to a row of memory cells in the memory block stacked with the first set of control circuits 510. Each sense amplifier is coupled to a bit line in the first semiconductor structure, where the bit line is coupled to a column of memory cells (e.g., a memory string) in the memory block stacked with the first set of control circuits 510. The sense amplifiers 514 are coupled to column decoder 516 to decode column addresses, and coupled to data line drivers 518 to receive signals to select/deselect bit lines. The remaining circuits 520 can include peripheral circuits such as a command decoder, an address buffer, a mode register, etc.

In some implementations, the first set of the peripheral circuits 510 occupies a larger area in XY plane than the corresponding memory block. For example, both the width and the length of the first set of the peripheral circuits 510 are greater than the width 502 and the length 504. When the first semiconductor structure and the second semiconductor structure are stacked together along Z direction, the first set of control circuits 510 only partially overlap with the corresponding memory block in the plan view (e.g., XY plane) along Z direction. In some implementations, the word line drivers 512 and the data line drivers 518 do not overlap with the corresponding memory block in the plan view. For example, the word line drivers 512 are positioned between two adjacent memory blocks (e.g., along X direction) in the plan view, and the data line drivers 518 are positioned between two adjacent memory blocks (e.g., along Y direction) in the plan view. As such, in order to properly stack memory blocks with their corresponding set of control circuits to form a bonded chip, the memory blocks in the first semiconductor structure need to be spaced from each other (e.g., to leave space for the word line drivers 512 and data line drivers 518). This can limit the memory cell density of the first semiconductor structure, hindering the further reduction of the size of the bonded chip.

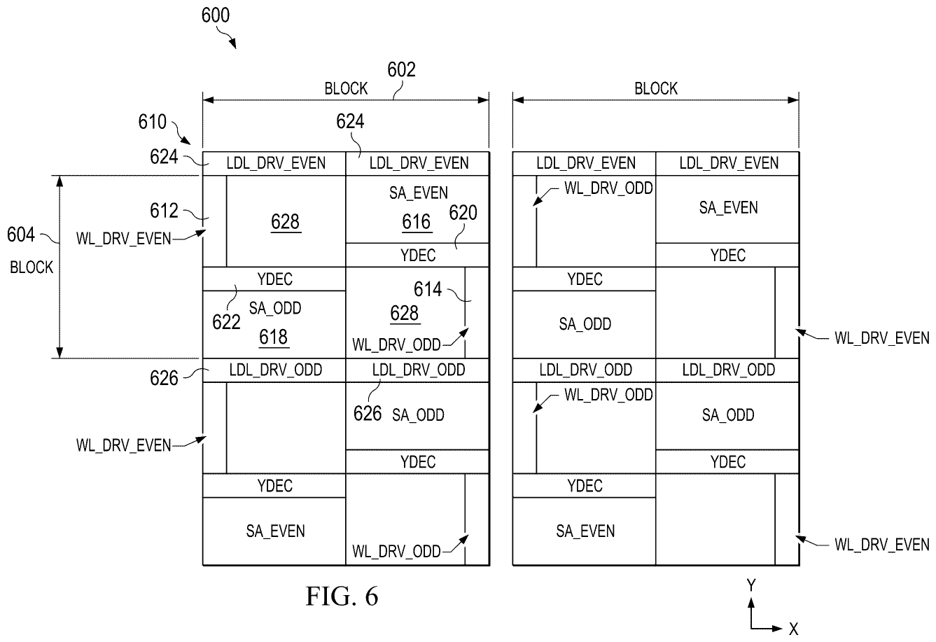

FIG. 6 illustrates a plan view (e.g., in the XY plane) of another example second semiconductor structure 600 (e.g., the second semiconductor structure 104 in FIGS. 1A and 1B), according to one or more implementations of the present disclosure. A width 602 represents a width (e.g., along X direction) of a memory block of the first semiconductor structure (e.g., the first semiconductor structure 102 of FIGS. 1A and 1B) that is coupled to a corresponding set of control circuits of the second semiconductor structure. For example, each set of control circuits is stacked with a corresponding memory block along the vertical direction (e.g., Z direction). A length 604 represents the length (e.g., along Y direction) of the memory block. As shown in FIG. 6, the second semiconductor structure 500 can include multiple sets of control circuits that are stacked with multiple adjacent memory blocks. For ease of explanation, a first set of control circuits 610 is described in detail, and the remaining sets of control circuits can be the same or substantially similar to the first set of control circuits 610.

As shown in FIG. 6, the first set of control circuits can include a driver circuit including a first set of word line drivers 612 and a second set of word line drivers 614, a sensing circuit including a first set of sense amplifiers 616 and a second set of sense amplifiers 618, first column decoder 620 coupled to the first set of sense amplifiers 616, second column decoder 622 coupled to the second set of sense amplifiers 618, first data line drivers 624 coupled to the first set of sense amplifiers 616, and second data line drivers 626 coupled to the second set of sense amplifiers 618. The first set of control circuits 610 can include remaining circuits 628 including such as a command decoder, an address buffer, a mode register, etc.

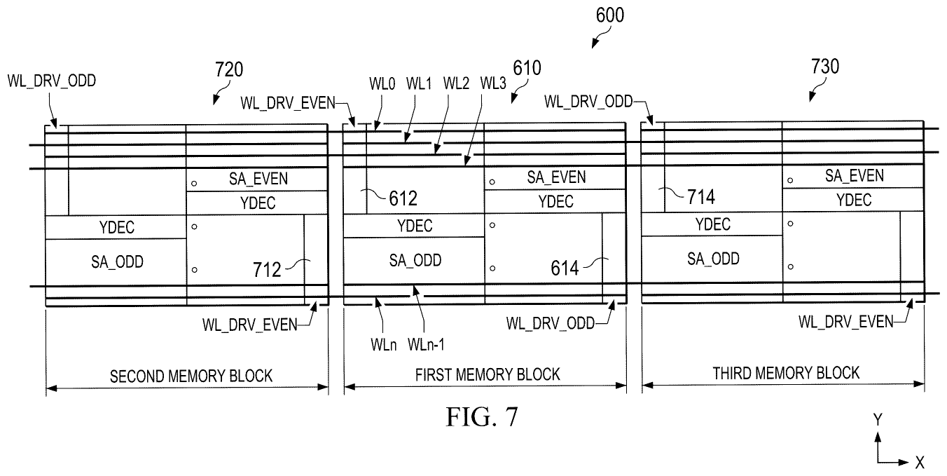

Referring to FIG. 7, which is a plan view of an example memory device having the second semiconductor structure 600, memory cells in adjacent memory blocks can share word lines (e.g., local word lines). In some implementations, the second semiconductor structure 600 can include the first set of control circuits 610 (e.g., coupled to and stacked with a first memory block in the first semiconductor structure), a second set of control circuits 720 (e.g., coupled to and stacked with a second memory block in the first semiconductor structure) on a first side along X direction of the first set of control circuits 610, and a third set of control circuits 730 (e.g., coupled to and stacked with a third memory block in the first semiconductor structure) on a second side along X direction of the first set of control circuits 610.

In some implementations, word lines are coupled to corresponding word line drivers in an interleaving way. Word lines coupled to memory cells in the first memory block can be grouped into two groups. For example, the word lines coupled to memory cells in the first memory block are numbered in order (e.g., consecutively from 0 to n). A first group of word lines include even-numbered word lines (e.g., WL0, WL2, WL4, . . . ), and a second group of word lines include odd-number word lines (e.g., WL1, WL3, WL5, . . . ). In some implementations, the first group of word lines are also coupled to memory cells in the second memory block. The first group of word lines are coupled to corresponding word line drivers of the first set of word line drivers 612. The second group of the word lines are also coupled to memory cells in the third memory block. The second group of word lines are coupled to corresponding word line drivers of the second set of word line drivers 614.

In some implementations, the first set of control circuits 610 share the use of word line drivers with the second set of control circuits 720 and the third set of control circuits 730. For example, the word line drivers (e.g., the first set of word line drivers 612) coupled to even-numbered word lines in the upper half of the first memory block are included in the first set of control circuits 610; the word line drivers (e.g., the third set of word line drivers 712) coupled to even-numbered word lines in the lower half of the first memory block are included in the second set of control circuits 720; the word line drivers (e.g., the fourth set of word line drivers 714) coupled to odd-numbered word lines in the upper half of the first memory block are included in the third set of control circuits 730; and the word line drivers (e.g., the second set of word line drivers 614) coupled to odd-numbered word lines in the lower half of the first memory block are included in the first set of control circuits 610.

Referring back to FIG. 6, when the second semiconductor structure 600 are stacked with its the first semiconductor structure along Z direction, the driver circuit including the first set of word line drivers 612 and the second set of word line drivers 614 overlaps with the corresponding memory block in the plan view (e.g., XY plane) along z direction. In some other implementations, the driver circuit including the first set of word line drivers 612 and the second set of word line drivers 614 partially overlaps with the corresponding memory block in the plan view, while partially overlaps with the gap area between the corresponding memory block and its adjacent memory block. As compared to the scenario illustrated in FIG. 5 where the word line drivers 512 overlap with the gap area between two adjacent memory blocks, the gap area needed between adjacent memory blocks in the first semiconductor structure can be reduced. This can increase the memory cell density of the first semiconductor structure, and further reduce the size of the bonded chip including the first semiconductor structure and the second semiconductor structure 600.

In some implementations, the first and second sets of word line drivers 612, 614, the first and second sets of sense amplifiers 616, 618, and the first and second column decoders 620, 622 overlap with the corresponding memory block in the plan view, which may require a compact layout of the above peripheral circuits. For example, a sun of widths (e.g., along X direction) of the first set of sense amplifiers 616 and the second set of sense amplifiers 618 is less than or equal to the width 602. A sum of lengths (e.g., along Y direction) of the first set of word line drivers 612, the first set of sense amplifiers 616, and the first column decoder 620 is less than or equal to the length 604. A sum of lengths of the first set of sense amplifiers 616 and the first column decoder 620 is less than or equal to half of the length 604.

In some implementations, by connecting memory cells in two adjacent memory blocks to a same word line and by connecting word lines to corresponding word line drivers in an interleaving way, the memory array density of the first semiconductor structure can be increased. Further, the layout of the second semiconductor structure can be optimized (e.g., enabling the word line drivers 612, 614 to fit under the memory block in the plan view).

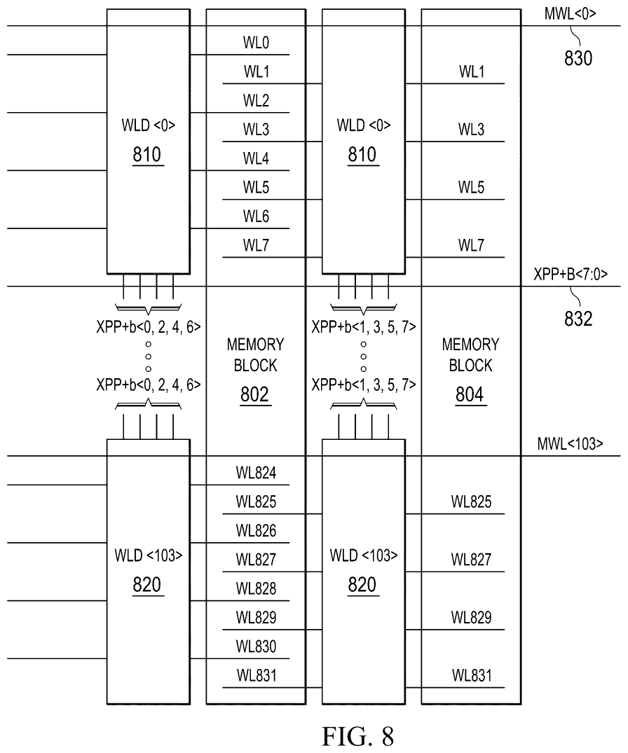

FIG. 8 illustrates an example memory device including example memory blocks of the first semiconductor structure and example word line drivers of the second semiconductor structure, according to some aspects of the present disclosure. Memory block 802 can be the first memory block that corresponds to the first set of control circuits 610 of FIG. 7, and memory block 804 can be the third memory block that corresponds to the third set of control circuits 730 of FIG. 7. In some implementations, word line drivers that each drives a word line coupled to memory cells in the memory block 802 can be arranged into different groups. As an example, each group of word line drivers can include 8 word line drivers that each drive one of 8 consecutively-numbered word lines. As shown in FIG. 8, memory cells in the memory block 802 are coupled to a total of 832 word lines numbered from 0 to 831. Odd-numbered word lines (e.g., WL1, WL3, WL7, . . . , WL831) are also coupled to memory cells in the adjacent memory block 804 (e.g., the third memory block stacked with the third set of control circuits 730 of FIG. 7), while even-numbered word lines (e.g., WL0, WL2, WL4, . . . , WL830) are also coupled to memory cells in an adjacent memory block (e.g., the second memory block stacked with the second set of control circuits 720 of FIG. 7, not shown in FIG. 8) on another side of the memory block 802. The first group of word line drivers 810 can include word line drivers that are coupled to WL0-7, the second group of word line drivers include word line drivers that are coupled to WL8-15, . . . , and the last group of word line drivers 820 can include word line drivers that are coupled to WL824-831. In some implementations, half of the each group of word line drivers (e.g., word line drivers coupled to even-numbered word lines) are positioned on one side of the memory block 802 in the plan view, and half of the each group of word line driver (e.g., word line drivers coupled to odd-numbered word lines) are positioned on the other side of the memory block 802.

In some implementations, the word line drivers are configured to select/deselect word lines based on two driving signals. A first driving signal 830 can be configured to select a group of word line drivers (e.g., a first group of word line drivers 810), and a second driving signal 832 can be configured to select one or more word line drivers (e.g., word line driver coupled to WL1) in the selected group of word line drivers. In some implementations, memory blocks in the first semiconductor structure are organized into memory banks. Each memory bank can have a corresponding set of global word lines and row decoders. The first driving signal 830 is generated by a global word line coupled to local word lines (e.g., WL0-8) of memory blocks 802, 804 in the memory bank, and the second driving signal 832 can be generated by the row decoder.

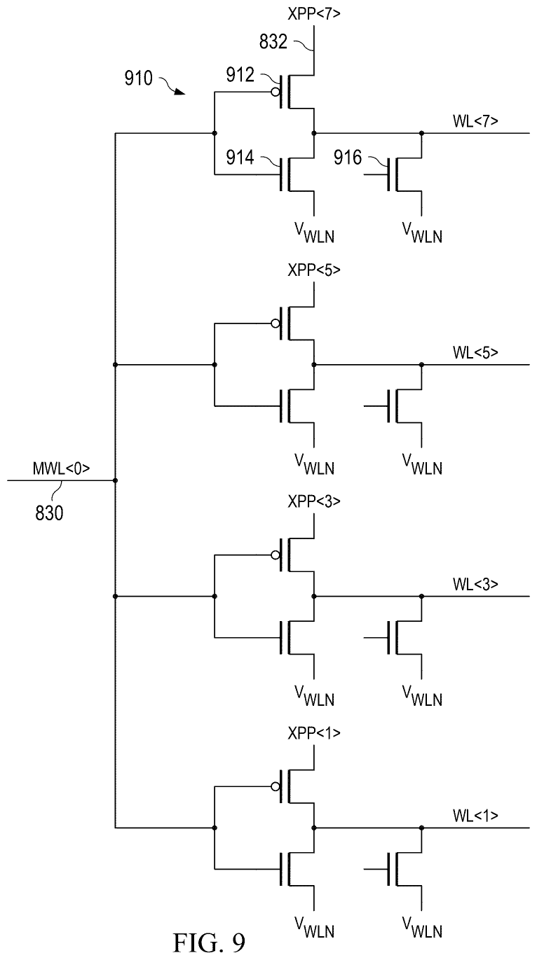

FIG. 9 illustrates schematic circuit diagrams of example word line drivers of FIG. 8, according to some aspects of the present disclosure. As illustrated in FIG. 8, half of the first group of word line drivers 810 are coupled to odd-number word lines (e.g., WL1, WL3, WL5, WL7). A word line driver 910 (e.g., word line driver coupled to WL7) can include a P-channel metal oxide semiconductor (PMOS) transistor 912, a N-channel metal oxide semiconductor (NMOS) transistor 914, and a keeping NMOS transistor 916. The gate of the PMOS transistor 912 receives the first driving signal 830, a first terminal (e.g., source) of the PMOS transistor 912 receives the second driving signal 832, and a second terminal (e.g., drain) of the PMOS transistor 912 is coupled to the local word line (e.g., WL7). The gate of the NMOS transistor 914 can receive the first driving signal 830, a first terminal (e.g., source) of the NMOS transistor 914 can receive a negative voltage V_{WLN}, and a second terminal (e.g., drain) of the NMOS transistor 914 is coupled to the local word line driver. The gate of the keeping NMOS transistor 916 can receive an inverted signal of the second driving signal 832, a first terminal (e.g., source) of the keeping NMOS transistor 916 can receive the negative voltage V_{WLN}, and a second terminal (e.g., drain) of the keeping NMOS transistor 916 can be coupled to the local word line.

In some implementations, in order to select a word line (e.g., WL7), the first driving signal 830 for the first group of word line drivers 810 can be set to a low voltage, so that the NMOS transistors 914 are switched off. The second driving signal 832 for word line driver of the selected word line can be set to a high voltage (e.g., Vₚₚ), so that the PMOS transistor 912 is switched on, and the keeping NMOS transistor 916 is switched off. As such, Vₚₚ is applied to the word line to select/enable the word line. The second driving signal 832 for word line drivers of unselected word lines in the first group of word lines can be set to a low voltage, so that the PMOS transistor 912 is switched off, and the keeping NMOS transistor 916 is switched on. As such, the word lines are deselected/disabled.

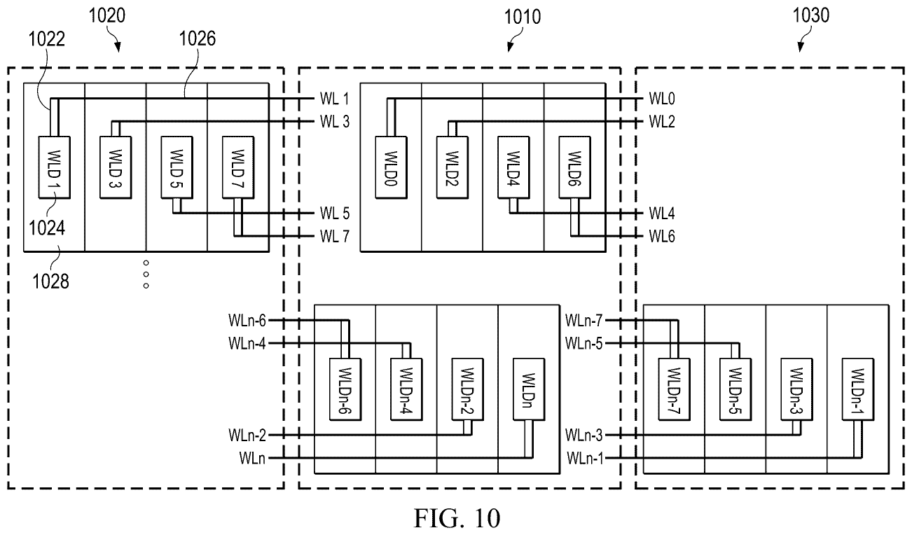

FIG. 10 illustrates example word lines and example word line drivers coupled to the word lines, according to some aspects of the present disclosure. Word lines coupled to memory cells in memory blocks 1010, 1020, 1030 of a first semiconductor structure (e.g., the first semiconductor structure 202 of FIG. 2) are each coupled to a corresponding word line driver (e.g., the word line driver 910 of FIG. 9) in a second semiconductor structure (e.g., the second semiconductor structure 204 of FIG. 2). As an example, memory cells in a first memory block 1010 are coupled to (n+1) word lines numbered from 0 to n. In some implementations, odd-numbered word lines are also coupled to memory cell in a second memory block 1020, and even-numbered word lines are also coupled to memory cell in a third memory block 1030.

As shown in FIG. 10, the first half of even-numbered word lines (e.g., WL0, WL2, WL4, WL6, . . . ) are each coupled to a word line driver (e.g., WLD0, WLD2, WLD4, WLD6, . . . ) that overlaps with the first memory block 1010 in a plan view perpendicular to a stacking direction (e.g., z direction). The first half of odd-numbered word lines (e.g., WL1, WL3, WL5, WL7, . . . ) are each coupled to a word line driver (e.g., WLD1, WLD3, WLD5, WLD7, . . . ) that overlaps with the second memory block 1020 in the plan view. The second half of even-numbered word lines (e.g., WLn-1, WLn-3, WLn-5, WLn-7, . . . , supposing that n is an odd number) are each coupled to a word line driver (e.g., WLDn-1, WLDn-3, WLDn-5, WLDn-7, . . . ) that overlaps with the third memory block 1030 in the plan view. The second half of odd-numbered word lines (e.g., WLn, WLn-2, WLn-4, WLn-6, . . . ) are each coupled to a word line driver (e.g., WLDn, WLDn-2, WLDn-4, WLDn-6, . . . ) that overlaps with the first memory block 1010 in the plan view.

In some implementations, each word line 1026 is coupled to a corresponding word line driver 1028 through bonding contacts (e.g., bonding contacts 219 and 221 of FIG. 2) that bond the first and second semiconductor structures together. In the first semiconductor structure, a word line 1026 is coupled to a bonding contact 1024 (e.g., bonding contact 221 of FIG. 2) through metal connection 1022 in an interconnect layer (e.g., interconnect layer 222 of FIG. 2) of the first semiconductor structure. The bonding contacts 1024 can be in contact with a corresponding bonding contact (e.g., bonding contact 219 of FIG. 2) in the second semiconductor structure at a bonding interface (e.g., bonding interface 206 of FIG. 2) between the first semiconductor structure and the second semiconductor structure. The corresponding bonding contact in the second semiconductor structure is coupled to the word line driver 1028 through an interconnect layer (e.g., the interconnect layer 216 of FIG. 2) of the second semiconductor structure.

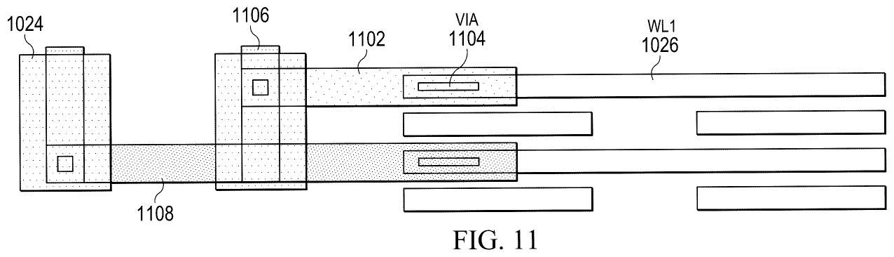

FIG. 11 illustrates example metal wiring that couple word lines 1026 in a first semiconductor structure to word line drivers in a second semiconductor structure, according to some aspects of the present disclosure. The interconnect layer (e.g., interconnect layer 222 of FIG. 2) of the first semiconductor structure can include more than one metal layer separated by ILD layers. Interconnect lines 1106 and via contacts 1104 formed in the ILD layer can be used to connect metal lines in different metal layers. In some implementations, the word line 1026 is coupled to the bonding contact 1024 of the first semiconductor structure through one or more metal layers in the interconnect layer. For example, the word line 1026 is connected to a first metal line 1102 in a first metal layer through a via contact 1104 in a first ILD layer. The first metal line 1102 is connected to a second metal line 1108 through an interconnect line 1106 in a second ILD layer between the first metal layer and the second metal layer. The second metal line 1107 is connected to the bonding contact 1024.

In some implementations, a word line 1026 can connect to the bonding contact 1024 through a metal line in one metal layer of the interconnect layer, or through metal lines in two or more metal layers of the interconnect layer, e.g., according to design and fabrication needs.

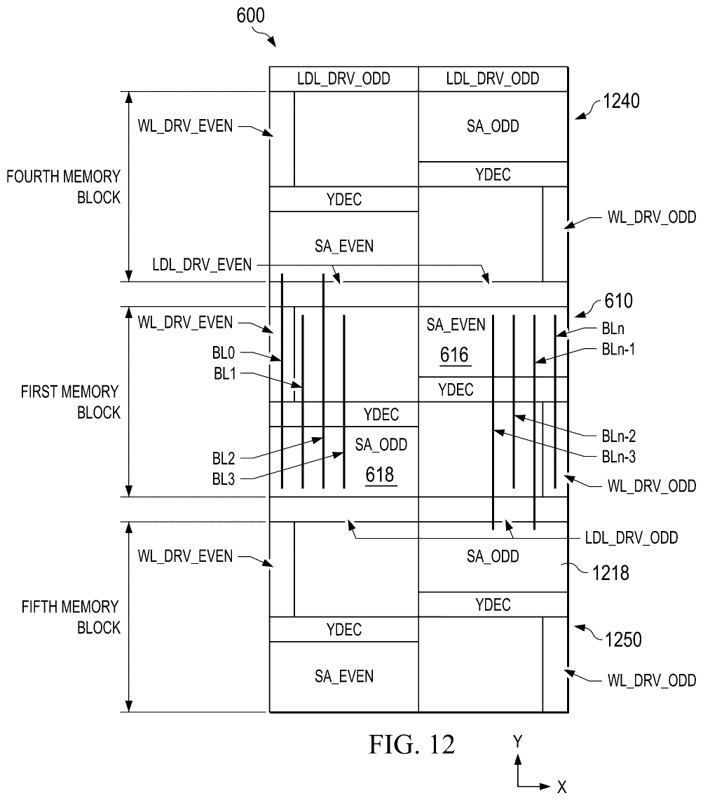

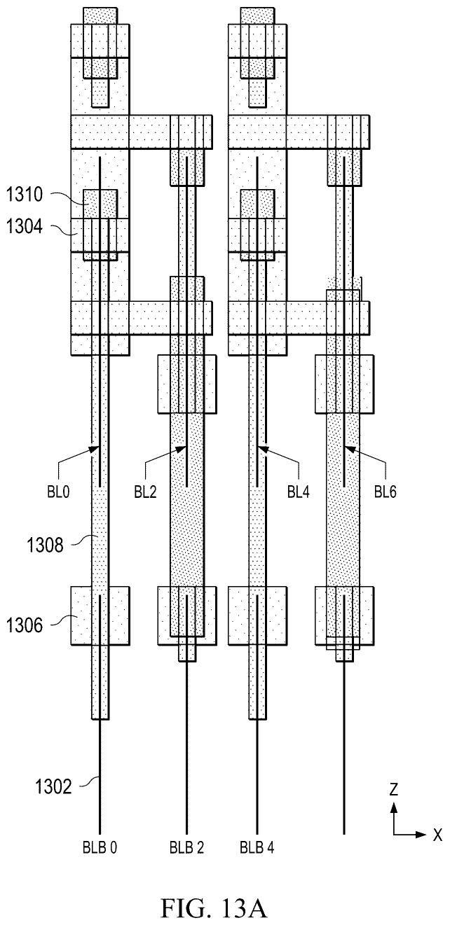

FIG. 12 illustrates a plan view of an example memory device having the second semiconductor structure 600 of FIG. 6, according to some aspects of the present disclosure. In some implementations, the second semiconductor structure 600 can include the first set of control circuits 610 (e.g., coupled to and stacked with the first memory block in the first semiconductor structure), a fourth set of control circuits 1240 (e.g., coupled to and stacked with a fourth memory block in the first semiconductor structure) on a first side along Y direction of the first set of control circuits 610, and a fifth set of control circuits 1250 (e.g., coupled to and stacked with a fifth memory block in the first semiconductor structure) on a second side along Y direction of the first set of control circuits 610.

In some implementations, bit lines in the first semiconductor structure are coupled to corresponding sense amplifiers in the second semiconductor structure in an interleaving way. For example, the bit lines coupled to memory strings in the first memory block are numbered in order (e.g., consecutively from 0 to n), and are grouped into two groups. A first group of bit lines can include even-numbered bit lines (e.g., BL0, BL2, BL4, . . . ), and a second group of bit lines include odd-number word lines (e.g., BL1, BL3, BL5, . . . ). In some implementations, the first group of bit lines are each coupled to a corresponding sense amplifier of the first set of sense amplifiers 616 or a third set of sense amplifiers 1216. The second group of bit lines are each coupled to corresponding sense amplifiers of the second set of sense amplifiers 618 or the fourth set of sense amplifiers 1218. For example, even-numbered bit lines in the left half of the first memory block are coupled to the third set of sense amplifiers 1216 included in the fourth set of control circuits 1240; even-numbered bit lines in the right half of the first memory block are coupled to the first set of sense amplifiers 616 included in the first set of control circuits 610; odd-numbered bit lines in the left half of the first memory block are coupled to second first set of sense amplifiers 618 included in the first set of control circuits 610; and odd-numbered bit lines in the right half of the first memory block are coupled to the fourth set of sense amplifiers 1218 included in the fifth set of control circuits 1250. In some implementations, bit lines coupled to memory strings in other memory blocks (e.g., the fourth and fifth memory blocks) are coupled to corresponding sense amplifiers in a similar interleaving way.

By connecting bit lines to corresponding sense amplifiers in an interleaving way, the memory array density of the first semiconductor structure can be increased, and the layout structure of the second semiconductor structure can be optimized (e.g., enabling the word line drivers the word line drivers 612, 614 to fit under the memory block in the plan view).

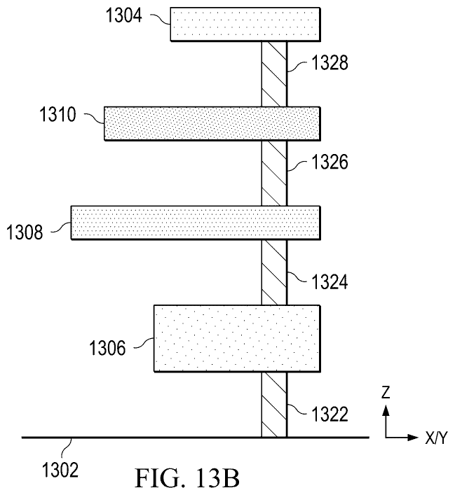

FIGS. 13A-13B illustrate example metal wiring that couples bit lines in a first semiconductor structure to sense amplifiers in a second semiconductor structure, according to some aspect of the present disclosure. In some implementations, bit lines 1302 in the first semiconductor structure are coupled to corresponding sense amplifiers through bonding contacts (e.g., bonding contacts 219 and 221 of FIG. 2) that bond the first semiconductor structure and the second semiconductor structure together. In the first semiconductor structure, a bit line 1302 is coupled to a bonding contact 1304 (e.g., bonding contact 221 of FIG. 2) through an interconnect layer (e.g., interconnect layer 222 of FIG. 2) of the first semiconductor structure. The bonding contact 1304 can be in contact with a corresponding bonding contact (e.g., bonding contact 219 of FIG. 2) in the second semiconductor structure at a bonding interface (e.g., bonding interface 206 of FIG. 2) between the first semiconductor structure and the second semiconductor structure. The corresponding bonding contact in the second semiconductor structure is coupled to the sense amplifier through an interconnect layer (e.g., the interconnect layer 216 of FIG. 2) of the second semiconductor structure.

In some implementations, in the first semiconductor structure, the interconnect layer (e.g., interconnect layer 222 of FIG. 2) of the first semiconductor structure can include more than one metal layer separated by ILD layers. Interconnect lines and/or via contacts formed in the ILD layer can be used to connect metal lines in different metal layers. In some implementations, the bit line 1302 is coupled to the bonding contact 1304 of the first semiconductor structure through one or more metal layers in the interconnect layer. For example, the bit line 1302 is connected to a first metal line 1306 in a first metal layer through a via contact or an interconnect line 1322 in a first ILD layer. The first metal line 1306 is connected to a second metal line 1308 in a second metal layer through a via contact or an interconnect line 1324 in a second ILD layer between the first metal layer and the second metal layer. The second metal line 1308 is connected to a third metal line 1310 in a third metal layer through a via contact or an interconnect line 1326 in a third ILD layer between the second metal layer and the third metal layer. The third metal line 1310 is connected to the bonding contact 1304 through a via contact or an interconnect line 1328 in a fourth ILD layer.

In some implementations, a bit line 1302 can connect to the bonding contact 1304 through a metal line in one metal layer of the interconnect layer, or through metal lines in two or more metal layers of the interconnect layer, e.g., according to design and fabrication needs.

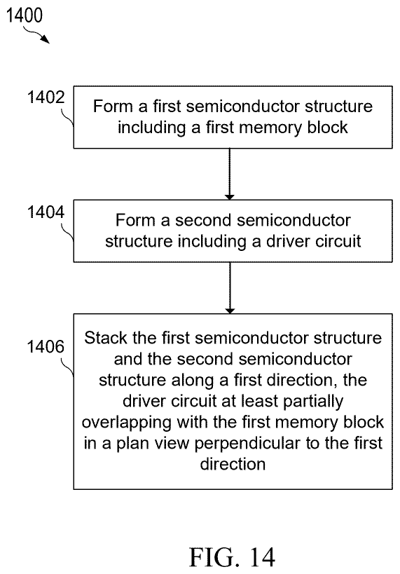

FIG. 14 is a flow chart of an example process 1400 of forming a memory device, according to some aspects of the present disclosure. The memory device can be the memory device 100 of FIG. 1A, the memory device 101 of FIG. 1B, or the memory device 200 of FIG. 2. The process 1400 includes operations (or steps) that can be performed with any suitable order and/or any combination.

At 1402, a first semiconductor structure (e.g., the first semiconductor structure 102 of FIG. 1A or 1B, or the first semiconductor structure 202 of FIG. 2) is formed. The first semiconductor structure can include a memory array that includes a first memory block (e.g., the memory block 802 of FIG. 8). The memory array can be the memory array 301 of FIG. 3 that includes DRAM memory cells. A word line is coupled to a row of memory cells in the memory block, and a bit line is coupled to a column of memory cells (e.g., a memory string) in the memory block.

At 1404, a second semiconductor structure (e.g., the second semiconductor structure 104 of FIGS. 1A-1B, the second semiconductor structure 204 of FIG. 2, or the second semiconductor structure 600 of FIGS. 6-7 and FIG. 12) is formed. The second semiconductor structure includes a driver circuit that includes word lines drivers (e.g., the word line driver 402 of FIG. 4, the word line drivers 612, 614 of FIG. 6, the word line drivers 810, 820 of FIG. 8, the word line driver 910 of FIG. 9, or the word line driver 1028 of FIG. 10). The word line drivers are coupled to word lines when the first and second semiconductor structures are bonded together to form a bonded chip.

In some implementations, the second semiconductor structure further includes a sensing circuit that includes sense amplifiers (e.g., the sense amplifier 404 of FIG. 4, or the sense amplifiers 616, 618 of FIGS. 6 and 12). The sense amplifiers are coupled to bit lines when the first and second semiconductor structures are bonded together to form a bonded chip.

At 906, the first semiconductor structure and the second semiconductor structure are stacked together along a first direction (e.g., Z direction). The driving circuit of the second semiconductor structure at least partially overlaps with the memory block of the first semiconductor structure in a plan view (e.g., in XY plane) perpendicular to the first direction.

In some implementations, word lines are coupled to corresponding word line driver in the driver circuit in an interleaving way. For example, an even-numbered word line is connected to a word line driver of a first set of word line drivers (e.g., the first set of word line drivers 612 of FIGS. 6-7), and an odd-numbered word line is connected to a word line driver of a second set of word line drivers (e.g., the second set of word line drivers 614 of FIGS. 6-7). In some implementations, even-numbered word lines coupled to memory cells in a first memory block are also coupled to memory cells in a second memory block adjacent to (e.g., along X direction, on a first side of) the first memory block, and odd-numbered word lines coupled to memory cells in the first memory block are also coupled to memory cells in a third memory block adjacent to (e.g., along X direction, on a second side of) the first memory block.

In some implementations, bit lines are coupled to corresponding sense amplifiers in the sensing circuit in an interleaving way. For example, an even-numbered bit line is coupled to a sense amplifier of a first set of sense amplifiers (e.g., the first set of sense amplifiers 616 of FIG. 6 and FIG. 12), and an odd-numbered bit line is connected to a sense amplifier of a second set of sense amplifiers (e.g., the second set of sense amplifiers 618 of FIG. 6 and FIG. 12).

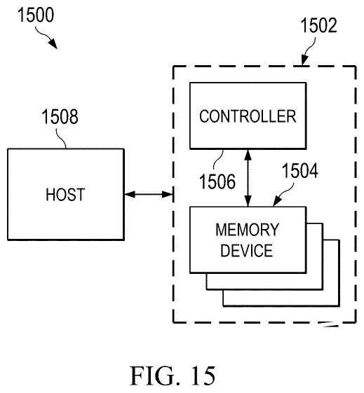

FIG. 15 illustrates a block diagram of a system 1500 having one or more semiconductor devices (e.g., memory devices), according to one or more implementations of the present disclosure. The system 1500 can be a mobile phone, a desktop computer, a laptop computer, a tablet, a server, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 15, the system 1500 can include a host device 1508 and a memory system 1502 having one or more memory devices 1504 and a memory controller 1506. Host device 1508 can include a processor of an electronic device, such as a central processing unit (CPU), or a system-on-chip (SoC), such as an application processor (AP). Host device 1508 can be configured to send or receive data to or from the one or more memory devices 1504.

A memory device 1504 can be any memory device disclosed herein, such as memory device depicted in any one of FIGS. 1-14. In some implementations, a memory device 1504 includes a DRAM memory. Memory controller 1506 (a.k.a., a controller circuit) is coupled to memory device 1504 and host device 1508. Consistent with implementations of the present disclosure, memory device 1504 can include a plurality of conductive interconnections through a cover layer that are in contact with conductive pads in a conductive pad layer, and memory controller 1506 can be coupled to memory device 1504 through at least one of the plurality of conductive interconnections. Memory controller 1506 is configured to control memory device 1504. Memory controller 1506 can manage data stored in memory device 1504 and communicate with host device 1508.

In some implementations, memory controller 1506 is designed/configured for operating in a low duty cycle environment like compact Flash (CF) cards, universal serial bus (USB) Flash drives, or other media for use in electronic devices, such as personal computers, digital cameras, mobile phones, etc. In some implementations, memory controller 1506 is designed/configured for operating in a high duty cycle environment like memory cards, graphic memory, or SSDs used as data storage for mobile devices, such as smartphones, tablets, laptop computers, etc., and enterprise storage arrays. Memory controller 1506 can be configured to control operations of memory device 1504, such as read, program (or write) operations. Memory controller 1506 can also be configured to manage various functions with respect to the data stored or to be stored in memory device 1504 including, but not limited to bad-block management, garbage collection, logical-to-physical address conversion, wear leveling, etc. In some implementations, memory controller 1506 is further configured to process error correction codes (ECCs) with respect to the data read from or written to memory device 1504. Any other suitable functions may be performed by memory controller 1506 as well, for example, formatting memory device 1504.

Memory controller 1506 can communicate with an external device (e.g., host device 1508) according to a particular communication protocol. For example, memory controller 1506 may communicate with the external device through at least one of various interface protocols, such as a USB protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,”

and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as glass, plastic, or sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate. The terms “operation” and “step” can be used interchangeably to describe a process.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A memory device, comprising:
a first semiconductor structure comprising a first memory block; and
a second semiconductor structure comprising a driver circuit,
wherein the first semiconductor structure and the second semiconductor structure are stacked along a first direction, and
wherein the driver circuit at least partially overlaps with the first memory block in a plan view perpendicular to the first direction.

2. The memory device of claim 1, wherein the first semiconductor structure further comprises a second memory block and a third memory block,
wherein word lines coupled to memory cells of the first memory block are arranged in order, and
wherein an even-numbered word line is coupled to memory cells of the second memory block, and an odd-numbered word line is coupled to memory cells of the third memory block.

3. The memory device of claim 2, wherein the first memory block is positioned between the second memory block and the third memory block along a second direction perpendicular to the first direction.

4. The memory device of claim 3, wherein the second memory block is positioned adjacent to the first memory block on a first side of the first memory block, and the third memory block is positioned adjacent to the first memory block on a second side of the first memory block.

5. The memory device of claim 2, wherein the driver circuit comprises a first set of word line drivers and a second set of word line drivers,
wherein the even-numbered word line is coupled to a corresponding word line driver of the first set of word line drivers, and
wherein the odd-numbered word line is coupled to a corresponding word line driver of the second set of word line drivers.

6. The memory device of claim 3, wherein the second semiconductor structure further comprises a sensing circuit, and
wherein the sensing circuit at least partially overlaps with the first memory block in the plan view.

7. The memory device of claim 6, wherein the sensing circuit comprises a first set of sense amplifiers and a second set of sense amplifiers,
wherein bit lines coupled to memory strings of the first memory block are arranged in order,
wherein an even-numbered bit line is coupled to a corresponding sense amplifier of the first set of sense amplifiers, and
wherein an odd-numbered bit line is coupled to a corresponding sense amplifier of the second set of sense amplifiers.

8. The memory device of claim 7, wherein the first semiconductor structure further comprises a fourth memory block and a fifth memory block,
wherein a first bit line coupled to a first memory string of the fourth memory block is coupled to a corresponding sense amplifier of the first set of sense amplifiers, and
wherein a second bit line coupled to a second memory string of the fifth memory block is coupled to a corresponding sense amplifier of the second set of sense amplifiers.

9. The memory device of claim 8, wherein the first memory block is positioned between the fourth memory block and the fifth memory block along a third direction perpendicular to the first direction and the second direction.

10. The memory device of claim 7, wherein the second semiconductor structure further comprises a first column decoder coupled to the first set of sense amplifiers, and a second column decoder coupled to the second set of sense amplifiers,
wherein the first column decoder and the second column decoder overlap with the first memory block in the plan view.

11. The memory device of claim 1, wherein the memory device comprises a DRAM memory device.

12. The memory device of claim 1, wherein the first semiconductor structure and the second semiconductor structure comprise bonding contacts that bond the first semiconductor structure and the second semiconductor structure together, wherein the bonding contacts are isolated by an isolating material.

13. The memory device of claim 12, wherein the first semiconductor structure further comprises a first interconnect layer positioned between the first memory block and the bonding contacts along the first direction,
wherein the first interconnect layer comprises metal layers, and
wherein a word line in the first memory block is connected to a respective one of the bonding contacts through at least one of the metal layers.

14. The memory device of claim 13, wherein a bit line in the first memory block is connected to a respective one of the bonding contacts through at least two of the metal layers.

15. A method of forming a memory device, comprising:
forming a first semiconductor structure based on forming a first memory block;
forming a second semiconductor structure based on forming a driver circuit; and
stacking the first semiconductor structure and the second semiconductor structure along a first direction, wherein the driver circuit at least partially overlaps with the first memory block in a plan view perpendicular to the first direction.

16. The method of claim 15, wherein the first semiconductor structure further comprises a second memory block and a third memory block,
wherein word lines coupled to memory cells of the first memory block are arranged in order, and
wherein an even-numbered word line is coupled to memory cells of the second memory block, and an odd-numbered word line is coupled to memory cells of the third memory block.

17. The method of claim 16, wherein the second memory block is positioned adjacent to the first memory block on a first side of the first memory block, and the third memory block is positioned adjacent to the first memory block on a second side of the first memory block.

18. The method of claim 16, wherein the driver circuit comprises a first set of word line drivers and a second set of word line drivers,
wherein the even-numbered word line is coupled to a corresponding word line driver of the first set of word line drivers, and
wherein the odd-numbered word line is coupled to a corresponding word line driver of the second set of word line drivers.

19. The method of claim 15, wherein the second semiconductor structure comprises a sensing circuit comprising a first set of sense amplifiers and a second set of sense amplifiers, wherein the sensing circuit at least partially overlaps with the first memory block in the plan view,
wherein bit lines coupled to memory strings of the first memory block are arranged in order,
wherein an even-numbered bit line is coupled to a corresponding sense amplifier of the first set of sense amplifiers, and
wherein an odd-numbered bit line is coupled to a corresponding sense amplifier of the second set of sense amplifiers.

20. A memory system, comprising:
a memory device comprising:
a first semiconductor structure comprising a first memory block; and
a second semiconductor structure comprising a driver circuit,
wherein the first semiconductor structure and the second semiconductor structure are stacked along a first direction, and
wherein the driver circuit at least partially overlaps with the first memory block in a plan view perpendicular to the first direction; and
a controller coupled to the memory device and configured to control the memory device.
